(19) United States
(12) Patent Application Publication
(10) Pub. No.: US 2008/0042170 A1
(43) Pub. Date: Feb. 21, 2008

(54) Image Sensor and Method for Manufacturing the Same

(76) Inventor: Chang Hun Han, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,200

(22) Filed: Aug. 21, 2007

(30) Foreign Application Priority Data
Aug. 21, 2006 (KR) 10-2006-0078862

(51) Int. Cl. H01L 27/146; H01L 21/8234

(52) U.S. Cl. 257/229; 438/60; 257/E27.133; 257/E21.617

(57) ABSTRACT

An image sensor and fabricating method thereof are provided. A gate electrode is formed on a semiconductor substrate with a photodiode on one side and a low-concentration drain on the other side. A silicide blocking pattern covers the photodiode, the gate electrode, and part of the low-concentration drain, such that an aperture exposes a portion of the low-concentration drain. A high-concentration drain is formed in the substrate under the aperture.

### CROSS-REFERENCE TO RELATED APPLICATION

The present application claims the benefit under 35 U.S.C. §119 of Korean Patent Application No. 10-2006-0078862, filed Aug. 21, 2006, which is hereby incorporated by reference in its entirety.

### BACKGROUND

An image sensor is a semiconductor device that converts an optical image into an electrical signal and can be categorized as a charge coupled device (CCD) image sensor or a Complementary Metal Oxide Semiconductor (CMOS) image sensor.

A CCD has the disadvantages of a complicated driving manner, large power consumption, and a complicated manufacturing process that often requires a multi-stage photo process.

Also, it is difficult for a CCD to integrate a control circuit, a signal processing circuit, an A/D converter, and other items on a CCD chip. Thus, a CCD also has difficulty in miniaturizing a product.

CMOS image sensors have recently been targeted to overcome the disadvantages of CCDs. A CMOS image sensor is a device that adopts a switching manner to sequentially detect the outputs of unit pixels by means of MOS transistors. A CMOS image sensor uses MOS transistors corresponding to the number of unit pixels and uses a control circuit and a signal processing circuit as peripheral circuits on a semiconductor substrate. Thus, the CMOS image sensor forms a photodiode and a MOS transistor in each unit pixel to sequentially detect electrical signals and implement an image.

A CMOS image sensor has the advantages of small power consumption and a simple manufacturing process that requires few photo process steps. Also, a CMOS image sensor can integrate a control circuit, a signal processing circuit, an A/D converter, and other items on a CMOS image sensor chip, providing the advantage of easily miniaturizing a product. Therefore, CMOS image sensors are often used in various applications such as digital still cameras and digital video cameras.

CMOS image sensors are also categorized according to the number of transistors in a unit pixel, for example, as 3T type CMOS image sensors, having three transistors, or 4T type CMOS image sensors, having four transistors.

A 3T type image sensor directly amplifies and outputs the charges generated by incident light on the photodiode. A 4T type image sensor amplifies and outputs the charges generated by incident light on the photodiode after storing it in a floating diffusion region.

In general, in a 3T type image sensor, it is difficult to precisely detect the variation of voltage depending on small changes in the amount of charge generated by the photodiode. A 4T type image sensor has the advantage of being able to detect the variation of voltage to a relatively precise degree, depending on small changes in the amount of charge generated by the photodiode.

### BRIEF SUMMARY

Embodiments of the present invention provide an image sensor and a method of manufacturing the same that can improve device characteristics by more precisely detecting small changes in the amount of charge generated by a photodiode.

An image sensor according to an embodiment includes: a gate electrode formed on a semiconductor substrate; a gate spacer optionally arranged on the side walls of the gate electrode; a photodiode arranged on one side of the gate electrode in the semiconductor substrate for generating charges by means of incident light; a low-concentration drain arranged on the other side of the gate electrode; a silicide blocking pattern covering the photodiode, the gate electrode, the gate spacer, and part of the low-concentration drain, and having an aperture exposing a portion of the low-concentration drain; and a high-concentration drain arranged under the aperture.

A method of manufacturing an image sensor according to an embodiment includes: forming a gate electrode on a semiconductor substrate; forming a photodiode by implanting ions at a low-concentration into a photodiode region formed on one side of the gate electrode; forming a low-concentration drain by implanting ions at a low-concentration into the other side of the gate electrode; optionally forming a gate spacer on the side walls of the gate electrode; forming a silicide blocking pattern covering the photodiode, the gate electrode, the gate spacer, and part of the low-concentration drain, where the silicide blocking pattern has an aperture exposing a portion of the low-concentration drain on the semiconductor substrate; and forming a high-concentration drain on the semiconductor substrate under the aperture using the silicide blocking pattern as an ion-implantation mask.

### BRIEF DESCRIPTION OF THE DRAWINGS

FIG. 1 is a circuit view of an image sensor according to an embodiment of the present invention.

FIG. 2 is a plan lay out view of the image sensor of FIG. 1.

FIG. 3 is a cross-sectional view taken along lines I-I′ of FIG. 2.

FIGS. 4 to 9 are cross-sectional views showing a method of manufacturing an image sensor according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

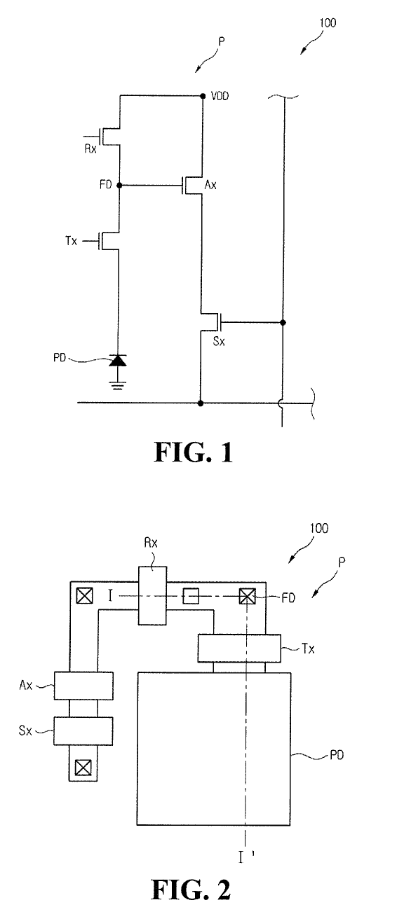

Referring to FIGS. 1 and 2, one pixel P of a plurality of pixels of an image sensor 100 comprises a photodiode PD that can sense external light and a plurality of transistors that can control the transfer and/or output of the charges stored in the photodiode PD.

In an embodiment, the pixel P of the image sensor 100 has four transistors.

The pixel P can include a photodiode PD for sensing light, a transfer transistor Tx, a reset transistor Rx, a select transistor Sx, and an access transistor Ax.

The photodiode PD can be connected by a transfer transistor Tx and a reset transistor Rx in series. The source of the transfer transistor Tx can be connected to the photodiode PD, and the drain of the transfer transistor Tx can be connected to the source of the reset transistor Rx.

A power voltage Vdd can be applied to the drain of the reset transistor Rx.

The drain of the transfer transistor Tx can serve as a floating diffusion layer FD. The floating diffusion layer FD can be connected to the gate of the access transistor Ax.

The select transistor Sx and the access transistor Ax can be connected in series, such that the source of the select transistor Sx and the drain of the access transistor Ax can be connected to each other.

The power voltage Vdd can be applied to the source of the access transistor Ax. The drain of the select transistor Sx can correspond to an output terminal, and the gate of the select transistor Sx can be applied with a select signal.

The potential of the floating diffusion layer FD can be the same as the power voltage Vdd by turning on the reset transistor Rx and then turning off the reset transistor Rx. Such an operation is defined as a reset operation.

If external light is incident on the photodiode PD, electron-hole pairs (EHP) can be generated within the photodiode PD so that the signal charges are accumulated within the photodiode PD.

As the transfer transistor Tx is turned on, the signal charges accumulated within the photodiode PD can be output to and stored in the floating diffusion layer FD.

Accordingly, the potential of the floating diffusion layer FD can be changed in proportion to the amount of charge output from the photodiode PD, thereby changing the potential of the gate of the access transistor Ax. If the select transistor Sx is turned on by means of the select signal, data can be output to the output terminal. After the data is output, the pixel P can perform the reset operation again. The pixel P can repeat the process and convert light into electrical signals to output them.

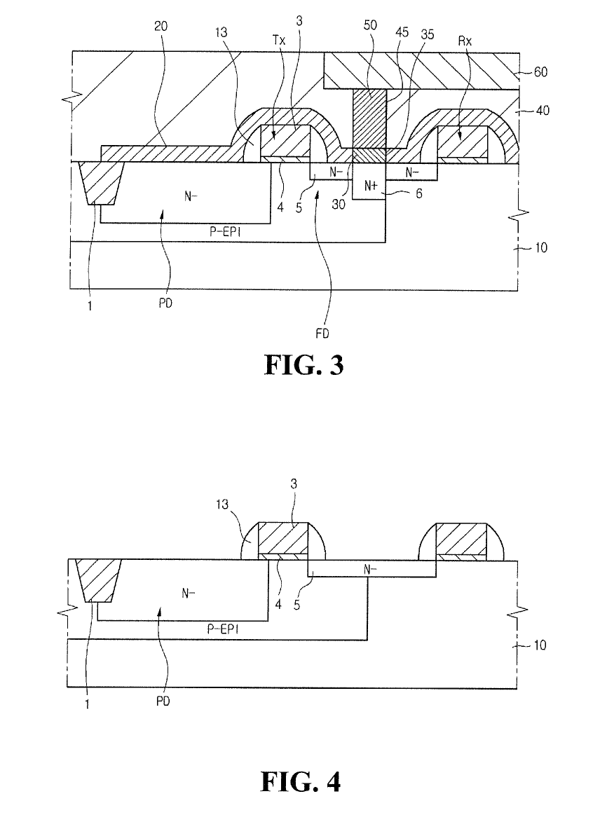

FIG. 3 is a cross-sectional view taken along lines I-I′ of FIG. 2.

Referring to FIG. 3, a plurality of device isolating parts 1 can be arranged in the semiconductor substrate 10. In an embodiment, the device isolating part 1 can be formed by forming a trench in the semiconductor substrate 10 and then arranging oxide inside the trench.

The photodiode PD can be arranged in the photodiode region formed in the semiconductor substrate 10. The photodiode PD can include a low-concentration doped N-type conductive impurity.

A driving region can be arranged in the region adjacent the photodiode region in the semiconductor substrate 10. Additionally, a plurality of transistors can be arranged in the driving region.

In an embodiment, the plurality of transistors can include the transfer transistor Tx, the reset transistor Rx, the select transistor Sx, and the access transistor Ax, as shown in FIGS. 1 and 2. The transfer transistor Tx and the reset transistor Rx are shown in FIG. 3, and the select transistor Sx and the access transistor Ax have a substantially similar structure to those of the transfer transistor Tx and the reset transistor Rx.

The transfer transistor Tx can comprise a gate 3, a gate insulating layer 4, a low-concentration drain 5, and a high-concentration drain 6. In an embodiment, the low-concentration drain 5 and the high-concentration drain 6 can form the floating diffusion layer FD.

The gate 3 can be arranged on the gate insulating layer 4, and a gate spacer 13 can be arranged on the side walls of the gate 3 to form a gate structure.

The photodiode PD can be arranged at one side of the gate 3, and the low-concentration drain 5 can be arranged at the other side of the gate 3.

In an embodiment, the photodiode PD and the plurality of transistors Tx, Rx, Sx, and Ax can be covered with a silicide blocking pattern 20. The silicide blocking pattern 20 can be an oxide film, a nitride film, or other appropriate material. In an embodiment, the thickness of the silicide blocking pattern 20 can be from about 200 Å to about 2,000 Å.

The silicide blocking pattern 20 can prevent silicide 30 from being formed on the photodiode PD.

The silicide blocking pattern 20 can include an aperture 35 opening to a portion of the low-concentration drain 5.

In an embodiment, the low-concentration drain 5 below the aperture 35 can be provided with a high-concentration drain 6 doped at high concentration with an N-type conductive impurity. The high-concentration drain 6 can correspond to the aperture 35, and the silicide blocking pattern 20 can serve as an ion implantation mask. In an embodiment, the width of the high-concentration drain 6 can be from about 0.16 μm to about 0.40 μm.

Providing a narrow high concentration drain 6 can reduce the capacitance (or leakage current) in the floating diffusion (FD) layer corresponding to the high-concentration drain 6.

In particular, the voltage difference (ΔV) generated from the photodiode PD is in proportion to the amount of charge (ΔQ) generated from the photodiode PD, and in inverse proportion to the capacitance (or leakage current) in the floating diffusion layer FD corresponding to the high-concentration drain 6.

Therefore, the capacitance can be reduced in order to increase the voltage difference (ΔV). Additionally, the area of the high-concentration drain 6 can be reduced in order to reduce the capacitance.

In many embodiments, as the area of the high-concentration drain 6 is reduced, the voltage difference (ΔV) generated by the photodiode PD is increased, thereby making it possible to more precisely detect the quantity of light incident on the photodiode PD.

Referring again to FIG. 3, silicide 30 can be arranged on the high-concentration drain 6 exposed by an aperture in the silicide blocking pattern 20.

Also, an interlayer dielectric layer 40 having a contact hole 45 can be arranged on the semiconductor substrate 10. A contact plug 50 can be arranged inside the contact hole 45, and a metal wiring 60 can be electrically connected to the contact plug 50. In an embodiment, the metal wiring 60 can be electrically connected to the gate of the access transistor Ax. In an embodiment, the contact plug 50 can be a metal plug.

FIGS. 4 to 9 are cross-sectional views showing a method of manufacturing an image sensor according to an embodiment.

Referring to FIG. 4, a device isolating part 1 can be formed on a semiconductor substrate 10. The device isolating part 1 can be formed by forming a trench in the semiconductor substrate 10 and then arranging oxide within the trench.

A P-type ions can be doped at low concentration in a driving region provided with transistors in the semiconductor substrate 10 to form a P well.

A gate insulating layer and a gate silicon layer, such as a polysilicon layer, can be sequentially formed over the semiconductor substrate 10, and the gate insulating layer and the gate silicon layer can be patterned so that a gate insulating layer pattern 4 and a gate 3 formed on the gate insulating pattern 4 are formed.

The driving region can be covered with a photoresist pattern, and the photodiode region can be selectively ion-implanted with an N-type impurity at a low concentration to form a low-concentration, N-type impurity, ion-implanted photodiode PD in the photodiode region.

After the photodiode PD is formed, the photoresist pattern covering the driving region can be removed. A photoresist pattern selectively covering the photodiode region can be formed, and N-type impurity can be ion-implanted at a low concentration into the driving region to form the low-concentration drain 5 on the side of the gate 3 opposite of the one in which the photodiode PD is formed.

An insulating layer (not shown) covering the gate 3 can be formed on the semiconductor substrate 10. In an embodiment, the insulating layer can include an oxide film, a nitride film, or both. The insulating layer can be etched by an etch back process so that a gate spacer 13 is formed on the side of the gate 3.

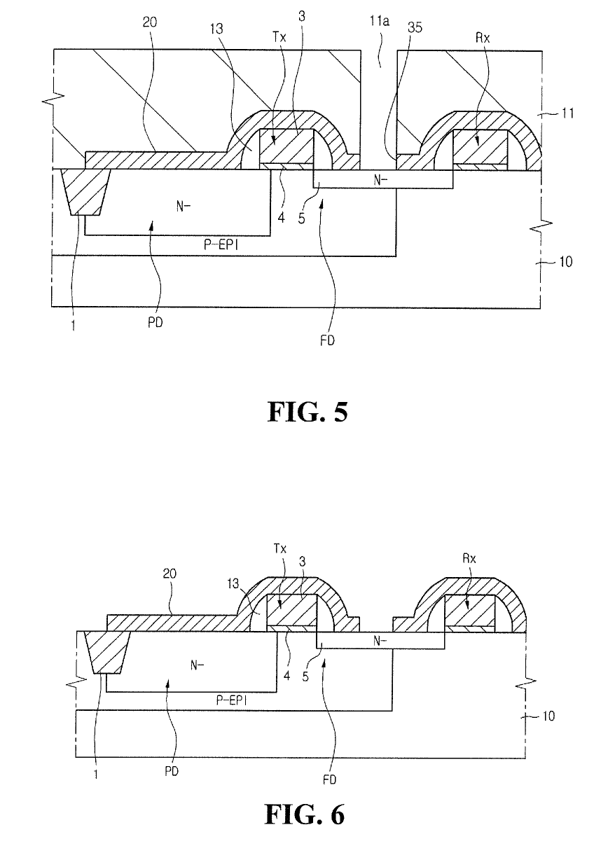

Referring to FIG. 5, a silicide blocking layer can be formed over the semiconductor substrate 10, and a photoresist film can be formed on the silicide blocking layer. The photoresist film can be patterned by an exposure process and a development process to form a photoresist pattern 11 having an aperture 11a in the portion corresponding to at least part of the low-concentration drain 5 below the silicide blocking layer.

The silicide blocking layer can be patterned using the photoresist pattern 11 as an etching mask to form a silicide blocking pattern 20. The silicide blocking pattern 20 has an aperture 35 formed in the portion corresponding to the aperture 11a of the photoresist pattern 11 to expose a portion of the low-concentration drain 5.

Referring to FIG. 6, the photoresist pattern 11 covering the silicide blocking pattern 20 can be removed.

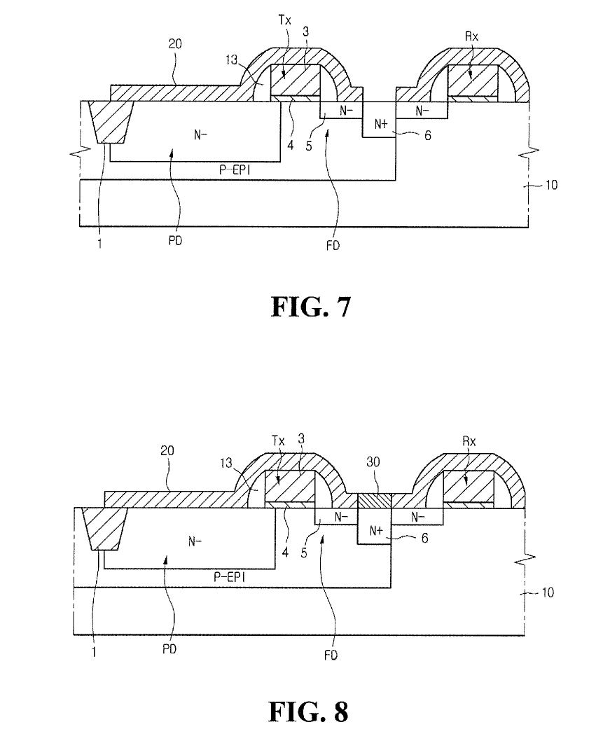

Referring to FIG. 7, the low-concentration drain 5 can be ion-implanted at a high concentration with an N-type impurity after the photoresist pattern 11 is removed. The silicide blocking pattern 20 can be used as an ion implantation mask so that the high-concentration drain 6 can be formed in at least the portion of the low-concentration drain 5 exposed through the aperture 35 of the silicide blocking pattern 20.

In an embodiment, the width of the high-concentration drain 6 is from about 0.16 μm to about 0.40 μm.

In an embodiment, the high-concentration drain 6 can be formed using the silicide blocking pattern 20 as an ion implantation mask, allowing the width of the high-concentration drain 6 to be greatly reduced, thereby making it possible to reduce the capacitance of the floating diffusion layer FD.

Referring to FIG. 8, after the high-concentration drain 6 is formed, a metal layer can be formed over the semiconductor substrate 10 including the silicide blocking layer. The metal layer can be annealed so that silicide 30 can be formed in the high-concentration drain 6 contacting the metal layer. Thereafter, the metal layer not including the silicide 30 can be removed from the silicide blocking pattern 20.

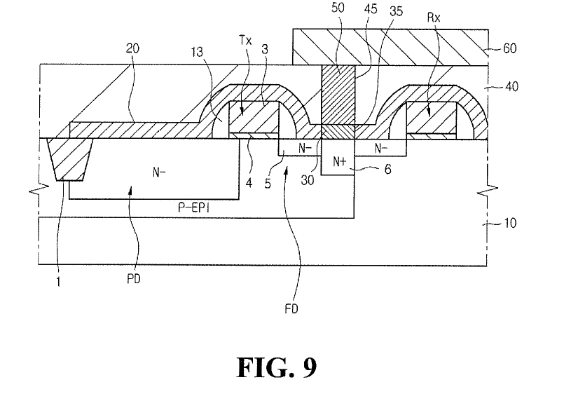

Referring to FIG. 9, after the silicide 30 is formed, an interlayer dielectric layer 40 having a contact hole 45 can be formed on the semiconductor substrate 10. The contact hole 45 can be formed in the portion of the interlayer dielectric layer 40 covering the silicide 30. Then, a contact plug 50 to fill the inside of the contact hole 45 can be formed. A metal wiring 60 contacting the contact plug 50 can be formed.

The capacitance of the floating diffusion layer can be reduced using the silicide blocking layer so that the amount of charge generated from the photodiode can be detected more precisely, improving the sensitivity and performance of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a gate electrode on a semiconductor substrate;
a photodiode arranged on a first side of the gate electrode;
a low-concentration drain arranged on a second side of the gate electrode opposite from the first side;
a silicide blocking pattern on the photodiode, the gate electrode, the gate spacer, and the low-concentration drain, wherein the silicide blocking pattern comprises an aperture exposing a portion of the low-concentration drain; and
a high-concentration drain arranged in the portion of the low-concentration drain corresponding to the aperture.

2. The image sensor according to claim 1, further comprising silicide on the high-concentration drain.

3. The image sensor according to claim 1, further comprising:
an interlayer dielectric layer having a contact hole formed over the aperture,
a metal plug inside the contact hole and connected to the high-concentration drain, and
a metal wiring connected to the metal plug.

4. The image sensor according to claim 1, wherein the width of the high-concentration drain is from about 0.16 μm to about 0.40 μm.

5. The image sensor according to claim 1, wherein the thickness of the silicide blocking pattern is from about 200 Å to about 2,000 Å.

6. The image sensor according to claim 1, wherein the low-concentration drain comprises an N-type impurity.

7. The image sensor according to claim 1, wherein the high-concentration drain comprises an N-type impurity.

8. The image sensor according to claim 1, wherein the photodiode comprises an N-type impurity.

9. The image sensor according to claim 1, further comprising a gate spacer on a side wall of the gate electrode.

10. A method of manufacturing an image sensor, comprising:
forming a gate electrode on a semiconductor substrate;
forming a photodiode by implanting ions at a low-concentration into a region on a first side of the gate electrode;
forming a low-concentration drain by implanting ions at a low-concentration into a region on a second side of the gate electrode opposite from the first side;
forming a silicide blocking pattern covering the photodiode, the gate electrode, and a first portion of the low-concentration drain, and exposing a second portion of the low-concentration drain through an aperture; and
forming a high-concentration drain in the exposed second portion of the low-concentration drain using the silicide blocking pattern as a ion-implantation mask.

11. The method according to claim 10, wherein the width of the high-concentration drain is from about 0.16 μm to about 0.40 μm.

12. The method according to claim 10, wherein the thickness of the silicide blocking pattern is from about 200 Å to about 2,000 Å.

13. The method according to claim 10, further comprising the steps of:
forming a metal layer on the silicide blocking pattern;
annealing the metal layer to form silicide on the high-concentration drain; and
removing the unsilicided metal layer.

14. The method according to claim 13, further comprising the steps of:
forming a contact hole over the silicide;
forming a metal plug in the contact hole; and
forming a metal wiring connected to the metal plug.

15. The method according to claim 10, wherein forming the photodiode comprises implanting N-type impurity ions.

16. The method according to claim 10, wherein forming the low-concentration drain comprises implanting N-type impurity ions.

17. The method according to claim 10, wherein the high-concentration drain comprises N-type impurity ions.

18. The method according to claim 10, further comprising forming a gate spacer on a side wall of the electrode.
